(19) United States
(12) Patent Application Publication
(10) Pub. No.: US 2024/0099057 A1
(43) Pub. Date: Mar. 21, 2024

(54) LIGHT-EMITTING PANEL AND PREPARATION METHOD THEREFOR, AND LIGHT-EMITTING APPARATUS

(71) Applicants: Hefei Xinsheng Optoelectronics Technology Co., Ltd., Hefei, Anhui (CN); BOE Technology Group Co., Ltd., Beijing (CN)

(72) Inventors: Jun LIU, Beijing (CN); Jun WANG, Beijing (CN); Ning LIU, Beijing (CN); Tongshang SU, Beijing (CN); Haidong WANG, Beijing (CN); Bin ZHOU, Beijing (CN); Xuehai GUI, Beijing (CN); Rong LIU, Beijing (CN)

(73) Assignees: Hefei Xinsheng Optoelectronics Technology Co., Ltd., Hefei, Anhui (CN); BOE Technology Group Co., Ltd., Beijing (CN)

(21) Appl. No.: 18/275,811

(22) PCT Filed: Nov. 18, 2021
(86) PCT No.: PCT/CN2021/131561

§ 371 Date: Aug. 4, 2023

(30) Foreign Application Priority Data
Mar. 19, 2021 (CN) 202110295622.1

(51) Int. Cl. H10K 59/12; H10K 59/122; H10K 59/124

(52) U.S. Cl. CPC H10K 59/1201; H10K 59/122; H10K 59/124

(57) ABSTRACT

A light-emitting panel has a light-emitting area and an isolation area adjacent to the light-emitting area The light-emitting panel comprises a base substrate and a barrier structure, wherein the barrier structure is arranged on one side of the base substrate and located in the isolation area, and comprises a first isolation pattern, a second isolation pattern, a third isolation pattern and a fourth isolation pattern, which are sequentially arranged in a stacked manner, and the first isolation pattern is closer to the base substrate than the fourth isolation pattern; and an orthographic projection of the first isolation pattern on the substrate is located in an orthographic projection of the second isolation pattern on the base substrate, and an orthographic projection of the third isolation pattern on the base substrate is located in an orthographic projection of the fourth isolation pattern on the base substrate.

### CROSS-REFERENCE OF RELATED APPLICATIONS

The present disclosure is a National Stage of International Application No. PCT/CN2021/131561, filed on Nov. 18, 2021, which claims the priority of a Chinese patent application with application number 202110295622.1, filed on Mar. 19, 2021, entitled “Light-emitting panel, and preparation method therefor, and light-emitting apparatus”, the entire contents of each are incorporated herein by reference in their entirety.

### TECHNICAL FIELD

The present disclosure relates to the technical field of illumination and display, and in particular, to a light-emitting panel, preparation method therefor, and light-emitting apparatus including the light-emitting panel.

### BACKGROUND

With more and more requirements for special-shaped light-emitting, the shape of the light-emitting area is different from the regular rectangular light-emitting area. It is necessary to design an isolation part to perform water vapor barrier isolation for the light-emitting functional layer and the cathode, so as to realize light-emitting of the special-shaped area. However, the isolation effect of the current isolation part is not ideal.

It should be noted that the information disclosed in the above Background section is only for enhancement of understanding of the background of the present disclosure, and therefore may contain information that does not form the prior art that is already known to those skilled in the art.

### SUMMARY

The purpose of the present disclosure is to overcome the above-mentioned deficiencies of the prior art, and to provide a light-emitting panel with better isolation effect, a preparation method of the light-emitting panel, and a light-emitting apparatus including the light-emitting panel.

According to one aspect of the present disclosure, there is provided a light-emitting panel having a light-emitting area and an isolation area adjacent to the light-emitting area, and the light-emitting panel includes: a substrate; a barrier structure, disposed on one side of the substrate and located in the isolation area; the barrier structure includes: a first isolation pattern, a second isolation pattern, a third isolation pattern and a fourth isolation pattern stacked in sequence, the first isolation pattern is closer to the substrate than the fourth isolation pattern; an orthographic projection of the first isolation pattern on the substrate is located within an orthographic projection of the second isolation pattern on the substrate, and an orthographic projection of the third isolation pattern on the substrate is located within an orthographic projection of the fourth isolation pattern on the substrate, and the orthographic projection of the third isolation pattern on the substrate is located within the orthographic projection of the second isolation pattern on the substrate.

In an exemplary embodiment of the present disclosure, the barrier structure further includes: a fifth isolation pattern disposed on one side of the fourth isolation pattern away from the substrate, wherein an orthographic projection of the fifth isolation pattern on the substrate is located within the orthographic projection of the fourth isolation pattern on the substrate, or the orthographic projection of the fourth isolation pattern on the substrate is located within an orthographic projection of the fifth isolation pattern on the substrate.

In an exemplary embodiment of the present disclosure, the barrier structure further includes: a sixth isolation pattern disposed between the substrate and the first isolation pattern, wherein the orthographic projection of the first isolation pattern on the substrate is located within an orthographic projection of the sixth isolation pattern on the substrate.

In an exemplary embodiment of the present disclosure, in the light-emitting area, the light-emitting panel includes: a plurality of pixel units arranged in an array, each of the pixel units includes at least three sub-pixels, each of the sub-pixels includes a thin film transistor and a light-emitting unit, the thin film transistor includes a gate electrode, a gate insulation layer, an active layer, a source electrode, a drain electrode and a planarization layer, the light-emitting unit includes a first electrode, a pixel definition layer, a light-emitting layer and a second electrode.

In an exemplary embodiment of the present disclosure, the first isolation pattern, the second isolation pattern and the sixth isolation pattern are provided in a same layer and with a same material as the source electrode and the drain electrode.

In an exemplary embodiment of the present disclosure, the third isolation pattern and the planarization layer are provided in a same layer and with a same material.

In an exemplary embodiment of the present disclosure, the fourth isolation pattern and the first electrode are provided in a same layer and with a same material.

In an exemplary embodiment of the present disclosure, the fifth isolation pattern and the pixel definition layer are provided in a same layer and with a same material.

According to another aspect of the present disclosure, a preparation method of a light-emitting panel is provided, including; providing a substrate, wherein the substrate has a light-emitting area and an isolation area adjacent to the light-emitting area; forming a first isolation pattern and a second isolation pattern sequentially on one side of the substrate and in the isolation area, wherein the orthographic projection of the first isolation pattern on the substrate is located within an orthographic projection of the second isolation pattern on the substrate; forming a third isolation pattern and a fourth isolation pattern sequentially on one side of the second isolation pattern away from the substrate, wherein an orthographic projection of the third isolation pattern on the substrate is located within an orthographic projection of the fourth isolation pattern on the substrate, and the orthographic projection of the third isolation pattern on the substrate is located within the orthographic projection of the second isolation pattern on the substrate.

In an exemplary embodiment of the present disclosure, the preparation method further includes: forming an active layer, a gate insulation layer and a gate electrode on one side of the substrate and in the light-emitting area, wherein the gate insulation layer is located between the active layer and the gate electrode; forming an interlayer dielectric layer on one side of the active layer or the gate electrode away from the substrate, and forming a first via hole on the interlayer dielectric laver, wherein the first via hole connected to the active layer; forming a source electrode and a drain electrode on one side of the interlayer dielectric layer away from the substrate, wherein the source electrode and the drain electrode are connected to the active layer through the first via hole; forming a planarization layer on one side of the source electrode and the drain electrode away from the substrate, and forming a second via hole on the planarization layer, wherein the second via hole is connected to the source electrode or the drain electrode; forming a first electrode on one side of the planarization layer away from the substrate, wherein the first electrode is connected to the source electrode or the drain electrode through the second via hole; forming a pixel definition layer on one side of the first electrode away from the substrate.

In an exemplary embodiment of the present disclosure, a first isolation layer and a second isolation pattern are sequentially formed in a patterning process of forming the source electrode and the drain electrode.

In an exemplary embodiment of the present disclosure, a third isolation layer is formed in a patterning process of forming the planarization layer, and the first isolation pattern is formed by etching the first isolation layer.

In an exemplary embodiment of the present disclosure, a sixth isolation pattern is further formed in the patterning process of forming the source electrode and the drain electrode, and the sixth isolation pattern is provided between the substrate and the first isolation patterns, and the orthographic projection of the first isolation pattern on the substrate is located within an orthographic projection of the sixth isolation pattern on the substrate.

In an exemplary embodiment of the present disclosure, the fourth isolation pattern is formed in a patterning process of forming the first electrode.

In an exemplary embodiment of the present disclosure, after forming the first electrode and the fourth isolation pattern, the preparation method further includes: forming a protective layer on the side of the first electrode away from the substrate and on sidewalls of the interlayer dielectric layer, the planarization layer and the first electrode; forming the third isolation pattern by ashing the third isolation layer, so that the orthographic projection of the third isolation pattern on the substrate is located within the orthographic projection of the fourth isolation pattern on the substrate, and the orthographic projection of the third isolation pattern on the substrate is located within the orthographic projection of the second isolation pattern on the substrate.

In an exemplary embodiment of the present disclosure, in the patterning process of forming the pixel definition layer, a fifth isolation pattern is formed on one side of the fourth isolation layer away from the substrate, and an orthographic projection of the fifth isolation pattern on the substrate is located within the orthographic projection of the fourth isolation pattern on the substrate, or the orthographic projection of the fourth isolation pattern on the substrate is located within an orthographic projection of the fifth isolation pattern on the substrate.

According to yet another aspect of the present disclosure, a light-emitting apparatus is provided, including the light-emitting panel described in any one of the above.

In the light-emitting panel and the preparation method therefor of the present disclosure, the barrier structure includes a first isolation pattern, a second isolation pattern, a third isolation pattern and a fourth isolation pattern stacked in sequence, and the first isolation pattern is closer to the substrate than the fourth isolation pattern; the orthographic projection of the first isolation pattern on the substrate is located within the orthographic projection of the second isolation pattern on the substrate, and the orthographic projection of the third isolation pattern on the substrate is located within the orthographic projection of the fourth isolation pattern on the substrate, and the orthographic projection of the third isolation pattern on the substrate is located within the orthographic projection of the second isolation pattern on the substrate. The substrate, the first isolation pattern, and the second isolation pattern form a first-layer “I”-shaped structure, and the second isolation pattern, the third isolation pattern, and the fourth isolation pattern form a second-layer “I”-shaped structure. The double-layer I-shaped structure increases the climbing difficulty of the light-emitting layer and the second electrode, weakens the climbing ability of the light-emitting layer and the second electrode, increases the barrier effect, and improves the reliability of the barrier structure. Moreover, even in the case of failure of the first-layer “I”-shaped structure, the second-layer “I”-shaped structure can still serve as a barrier.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Obviously, the drawings in the following description are only some embodiments of the present disclosure, and for those ordinary skilled in the art, other drawings can also be obtained from these drawings without inventive labor.

FIG. 1 is a schematic cross-sectional structural diagram of an exemplary embodiment of a light-emitting panel of the present disclosure.

FIG. 2 is a schematic top-view structure diagram of an exemplary embodiment of a light-emitting panel of the present disclosure.

FIG. 3 is a schematic flow chart of an exemplary embodiment of a preparation method of a light-emitting panel of the present disclosure.

FIGS. 4 to 10 are schematic structural diagrams of steps in the preparation method of the light-emitting panel of the present disclosure.

### EXPLANATION OF REFERENCE NUMBERS

1, substrate; 2, buffer layer; 3, active layer;
41, first gate insulation layer; 42, second gate insulation layer;
5, gate electrode;
6, interlayer dielectric layer; 61, first via hole;
71, first conductor layer; 72, second conductor layer; 73, third conductor layer;
74, source electrode; 75, drain electrode;
8, barrier structure; 81, first isolation pattern; 81a, first isolation layer; 82, second isolation pattern; 83, third isolation pattern; 83a, third isolation layer; 84, fourth
isolation pattern; 85, fifth isolation pattern; 86, sixth isolation pattern;
9, planarization material layer; 91, planarization layer; 92, second via hole;
10, first electrode; 11, protective layer; 12, pixel definition layer; 13, light-emitting layer; 14, second electrode;
A, light-emitting area; L, isolation area; S, border area.

### DETAILED DESCRIPTION

Exemplary embodiments will now be described more fully with reference to the accompanying drawings. Exemplary embodiments, however, can be embodied in various forms and should not be construed as limited to the embodiments set forth herein; rather, these embodiments are provided so that this disclosure will be thorough and complete, and will fully convey the concept of exemplary embodiments to those skilled in the art. The same reference numerals in the drawings denote the same or similar structures, and thus their detailed descriptions will be omitted. Furthermore, the drawings are merely schematic illustrations of the present disclosure and are not necessarily drawn to scale.

Although relative terms such as “top” and “bottom” are used in this specification to describe the relative relationship of one component of an icon to another component, these terms are used in this specification only for convenience, such as according to the direction of the example described in the drawing. It will be appreciated that if the device of the icon is turned upside down, the components described as on “top” will become the components on “bottom”. When a certain structure is on “top” of other structure, it may mean that a certain structure is integrally formed on top of other structure, or that a certain structure is “directly” arranged on top of other structure, or that a certain structure is “indirectly” arranged on top of other structure through another structure.

The terms “a”, “an”, “the”, “said” and “at least one” are used to indicate the presence of one or more elements/components/etc.; the terms “include” and “have” are used to indicate open inclusion and means that additional elements/components/etc. may be present in addition to the listed elements/components/etc.; the terms “first”, “second” and “third” etc. are only used as a marker, and are not limitations on the number of objects thereof.

As an emerging technology, customized OLED (Organic Electroluminesence Display) has attracted widespread attention. Currently, it mainly uses LTPS (Low Temperature Poly-Silicon) as the channel layer for backplate technology. Due to its customized luminescence, the light-emitting shape is inconsistent with the mainstream rectangle. It needs to design a barrier structure 8 (RIB) to perform the relevant barrier isolation for the organic light-emitting layer 13 (EL) and the cathode (Cathode), in order to increase pathways for blocking water vapor intrusion and improve the packaging reliability, and this method can match normal printing related process.

At present, the barrier structure 8 is mainly used to form an I-shaped structure of TiAlTi structure, but when the reflective anode (the material of which is ITO-Ag-ITO) is subsequently formed, the etching effect of the etching solution on the Al in the I-shaped structure is faster. When the reflective anode is wet-etched, if the I-shaped metal structure is not protected, it will cause serious over-etching of Al in the I-shaped metal. Over-etching can cause Ti on top of the I-shaped shape to collapse, leading to the failure of the I-shaped shape and even complete absence of Al in the structure, and making it unable to block the organic light-emitting layer 13 and cathode. Therefore, when the reflective anode is etched, the TiAlTi structure needs to be protected. After the reflective anode is etched, a process is added to etch and indent Al to form an I-shaped structure, which increases the complexity of the process by adding a mask, etch and strip process.

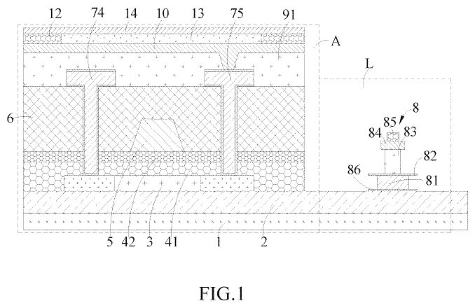

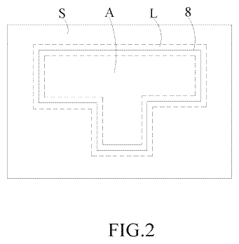

Embodiments of the present disclosure provide a light-emitting panel, as shown in FIG. 1 and FIG. 2, which are schematic structural diagrams of the light-emitting panel. The light-emitting panel has a light-emitting area A (also referred to as a display area (Active Area, abbreviated as Area A)) and an isolation area L adjacent to the light-emitting area A. A frame area S is also provided on the periphery of the isolation area L, and the frame area S can be provided with various leads and driving circuits. The light-emitting panel includes a substrate 1 and a barrier structure 8; the barrier structure 8 is arranged on one side of the substrate 1 and is located in the isolation area L. The barrier structure 8 includes: a first isolation pattern 81, a second isolation pattern 82, a third isolation pattern 83 and a fourth isolation pattern 84 arranged in sequence, where the first isolation pattern 81 is closer to the substrate 1 than the fourth isolation pattern 84. The orthographic projection of the first isolation pattern 81 on the substrate 1 is located within the orthographic projection of the isolation pattern 82 on the substrate 1, the orthographic projection of the third isolation pattern 83 on the substrate 1 is located within the orthographic projection of the fourth isolation pattern 84 on the substrate 1, and the orthographic projection of the third isolation pattern 83 on the substrate 1 is located within the orthographic projection of the second isolation pattern 82 on the substrate 1.

In the light-emitting panel and the preparation method therefor of the present disclosure, the substrate 1, the first isolation pattern 81 and the second isolation pattern 82 form a first-layer “I”-shaped structure; the second isolation pattern 82, the third isolation pattern 83 and the fourth isolation pattern 84 form a second-layer “I”-shaped structure. The double-layer “I”-shaped structure increases the climbing difficulty of the light-emitting layer 13 and the second electrode 14, so that the climbing ability of the light-emitting layer 13 and the second electrode 14 is weakened, the barrier effect is increased, and the reliability of the barrier structure 8 is improved. Moreover, even in the case of failure of the first-layer “I”-shaped structure, the second-layer “I”-shaped structure can still serve as a barrier.

Since the light-emitting panel can be made into a light-emitting panel with any light-emitting shape, the shape of the barrier structure 8 extending along the edge of the light-emitting area A can be any shape. In FIG. 2, the shapes of the three areas (the light-emitting area A, the isolation area L, and the frame area S) are only examples and are not limited.

In this exemplary embodiment, the substrate 1 may be a glass substrate or a PI (Polyimide) substrate.

A buffer layer 2 is provided on one side of the substrate 1.

In the light-emitting area A, the light-emitting panel may include a plurality of pixel units arranged in an array. Each pixel unit includes at least three sub-pixels, and each sub-pixel includes a thin film transistor and a light-emitting unit.

Specifically, the structure of the thin film transistor is as follows: an active layer 3 is provided on the side of the buffer layer 2 away from the substrate 1. A first gate insulation layer 41 is provided on the side of the active layer 3 away from the substrate 1, and the material of the first gate insulation layer 41 may be silicon oxide. A second gate insulation layer 42 is provided on the side of the first gate insulation layer 41 away from the substrate 1, and the material of the second gate insulation layer 42 may be silicon nitride. A gate electrode 5 is provided on the side of the second gate insulation layer 42 away from the substrate 1, and the material of the gate electrode 5 may be molybdenum, nickel, nickel-manganese alloy, nickel-chromium alloy, nickel-molybdenum-iron alloy, and the like. An interlayer dielectric layer 6 is provided on the side of the gate electrode 5 away from the substrate 1, the material of the interlayer dielectric layer 6 can be silicon oxide. A first via hole 61 is provided on the interlayer dielectric layer 6, and the first via hole 61 is connected to the active layer 3. A source electrode 74 and a drain electrode 75 are provided on the side of the interlayer dielectric layer 6 away from the substrate 1. The source electrode 74 and the drain electrode 75 are connected to the active layer 3 through the first via hole 61. The material of the source electrode 74 and the drain electrode 75 may be TiAlTi (titanium-aluminum-titanium three-layer). A planarization layer 91 is provided on the side of the source electrode 74 and the drain electrode 75 away from the substrate 1, and a second via hole 92 is provided on the planarization layer 91. The second via hole 92 can be connected to the source electrode 74. Of course, the second via hole 92 can also be connected to the drain electrode 75.

Specifically, the structure of the light-emitting unit is as follows: a first electrode 10 is provided on the side of the planarization layer 91 away from the substrate 1, the first electrode 10 is connected to the source electrode 74 through the second via hole 92, and the material of the first electrode 10 can be ITO-Ag-ITO (indium tin oxide-silver-indium tin oxide). Of course, in the case where the second via hole 92 is connected to the drain electrode 75, the first electrode 10 is connected to the drain electrode 75 through the second via hole 92. A pixel definition layer 12 is provided on the side of the first electrode 10 away from the substrate 1. A third via hole is provided on the pixel definition layer 12. The third via hole is connected to the first electrode 10, and the first electrode 10 may be an anode. A light-emitting layer 13 is provided in the third via hole, and the light-emitting layer 13 is in contact with the first electrode 10. A second electrode 14 is provided on the side of the light-emitting layer 13 away from the substrate 1, and the second electrode 14 may be a cathode.

The thin film transistor described above is of the top-gate type. Of course, in other exemplary embodiments of the present disclosure, the thin-film transistor may also be of a bottom-gate type or a double-gate type.

In the isolation area L, a sixth isolation pattern 86 is provided on the side of the buffer layer 2 away from the substrate 1, and a first isolation pattern 81 is provided on the side of the sixth isolation pattern 86 away from the substrate 1. A second isolation pattern 82 is provided on the side of the first isolation pattern 81 away from the substrate 1. A third isolation pattern 83 is provided on the side of the second isolation pattern 82 away from the substrate 1. A fourth isolation pattern 84 is provided on the side of the third isolation pattern 83 away from the substrate 1, and a fifth isolation pattern 85 is provided on the side of the fourth isolation pattern 84 away from the substrate 1.

The orthographic projection of the first isolation pattern 81 on the substrate 1 is located within the orthographic projection of the second isolation pattern 82 on the substrate 1, and the orthographic projection of the first isolation pattern 81 on the substrate 1 is located within the orthographic projection of the sixth isolation pattern 86 on the substrate 1. The sixth isolation pattern 86, the first isolation pattern 81 and the second isolation pattern 82 form a first-layer “I”-shaped structure.

The orthographic projection of the third isolation pattern 83 on the substrate 1 is located within the orthographic projection of the fourth isolation pattern 84 on the substrate 1, and the orthographic projection of the third isolation pattern 83 on the substrate 1 is located within the second isolation pattern 82 is in the orthographic projection on the substrate 1. The second isolation pattern 82, the third isolation pattern 83 and the fourth isolation pattern 84 form a second-layer “I”-shaped structure.

The double-layer “I”-shaped structure increases the climbing difficulty of the light-emitting layer 13 and the second electrode 14 (cathode), which weakens the climbing ability of the light-emitting layer 13 and the second electrode 14, increases the barrier effect, and improves the reliability of the barrier structure 8; and even in the case of failure of the first-layer “I”-shaped structure, the second-layer “I”-shaped structure can still serve as a barrier.

In addition, the fifth isolation pattern 85 further increases the height of the barrier structure 8, and the orthographic projection of the fifth isolation pattern 85 on the substrate 1 is located within the orthographic projection of the fourth isolation pattern 84 on the substrate 1, that is, the edge of the fifth isolation pattern 85 is concave relative to the edge of the fourth isolation pattern 84; or the orthographic projection of the fourth isolation pattern 84 on the substrate 1 is located within the orthographic projection of the fifth isolation pattern 85 on the substrate 1, that is, the edge of the fifth isolation pattern 85 is protruded relative to the edge of the fourth isolation pattern 84. That is to say, the edge of the fifth isolation pattern 85 is not aligned with the edge of the fourth isolation pattern 84, which weakens the climbing ability of the light-emitting layer 13 and the second electrode 14, increases the barrier effect, and improves the reliability of the barrier structure 8.

It should be noted that the specific structure of the barrier structure 8 is not limited to the above description. For example, the barrier structure 8 may not include the fifth isolation pattern 85, that is, a double-layer “I”-shaped structure is formed.

In addition, the barrier structure 8 may not include the sixth isolation pattern 86, and the first isolation pattern 81 and the second isolation pattern 82 as well as the substrate 1 may also form a first-layer “I”-shaped structure. The same isolation effect can also be achieved.

In the present exemplary embodiment, the first isolation pattern 81, the second isolation pattern 82 and the sixth isolation pattern 86 are provided in the same layer and with the same material as the source electrode 74 and the drain electrode 75. That is, the material of the sixth isolation pattern 86 is titanium, the material of the first isolation pattern 81 is aluminum, and the material of the second isolation pattern 82 is titanium.

In the present exemplary embodiment, the third isolation pattern 83 and the planarization layer 91 are provided in the same layer and with the same material. Since the thickness of the planarization layer 91 is thick, the thickness of the third isolation pattern 83 is also thick; the overall height of the second-layer “I”-shaped structure is increased, thereby further increasing the climbing difficulty of the light-emitting layer 13 and the second electrode 14, so as to weaken the climbing ability of the light-emitting layer 13 and the second electrode 14, increase the barrier effect and improve the reliability of the barrier structure 8.

In this exemplary embodiment, the fourth isolation pattern 84 may be provided in the same layer and with the same material as the first electrode 10. That is, the material of the fourth isolation pattern 84 may be ITO-Ag-ITO (indium tin oxide-silver-indium tin oxide).

In this exemplary embodiment, the fifth isolation pattern 85 may be provided in the same layer and with the same material as the pixel definition layer 12.

It should be noted that the so-called “provided in the same layer and with the same material” refers to forming through one same patterning process, which will be described in detail in the preparation method of the light-emitting panel below.

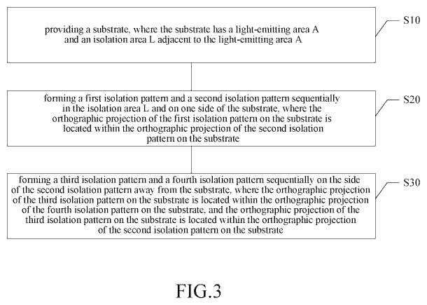

Further, an embodiment of the present disclosure provides a preparation method of a light-emitting panel. Referring to the schematic flow chart of the preparation method of the light-emitting panel shown in FIG. 3, the preparation method of the light-emitting panel may include the following steps: at step S10, providing a substrate 1, where the substrate 1 has a light-emitting area A and an isolation area L adjacent to the light-emitting area A; at step S20, forming a first isolation pattern 81 and a second isolation pattern 82 sequentially in the isolation area L and on one side of the substrate 1, where the orthographic projection of the first isolation pattern 81 on the substrate 1 is located within the orthographic projection of the second isolation pattern 82 on the substrate 1; at Step S30, forming a third isolation pattern 83 and a fourth isolation pattern 84 sequentially on the side of the second isolation pattern 82 away from the substrate 1, where the orthographic projection of the third isolation pattern 83 on the substrate 1 is located within the orthographic projection of the fourth isolation pattern 84 on the substrate 1, and the orthographic projection of the third isolation pattern 83 on the substrate 1 is located within the orthographic projection of the second isolation pattern 82 on the substrate 1.

Each step of the preparation method of the light-emitting panel will be described in detail below.

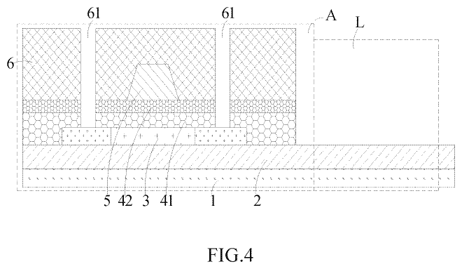

Refer to FIG. 4.

A substrate 1 is provided, and a buffer layer 2 is deposited and formed on one side of the substrate 1.

An active material layer is deposited and formed on the side of the buffer layer 2 away from the substrate 1, and the material of the active material layer can be SiN, SiO or a-Si (amorphous silicon). The thickness of SiN is greater than or equal to 0.3 μm and less than or equal to 0.7 μm; the thickness of SiO is greater than or equal to 1.0 μm and less than or equal to 1.2 μm; the thickness of a-Si is about 0.05 μm. Then, the active material layer is dehydrogenated, so as to avoid a hydrogen explosion phenomenon during the excimer laser crystallization (ELA) process, and the dehydrogenation condition may be 300° C. to 350° C. After the dehydrogenation is completed, the excimer laser crystallization process is performed to convert the amorphous silicon into polycrystalline silicon. Finally, use a digital exposure machine or a mask to form a silicon island mask, and then dry-etch the active material laver, which can be dry-etched using CF4+O2: then wet strip the silicon island mask to form a silicon island pattern (active layer 3). A mask is formed in the channel region, and ion implantation is performed on the non-channel region to conduct the polysilicon doping conductive, with the use of phosphine or borane for doping.

A first gate insulation layer 41 is deposited on the side of the active layer 3 away from the substrate 1. The material of the first gate insulation layer 41 can be SiO, and the thickness of SiO is greater than or equal to 0.03 μm and less than or equal to 0.06 μm. A second gate insulation layer 42 is deposited on the side of the first gate insulation layer 41 away from the substrate 1. The material of the second gate insulation layer 42 may be SiN, and the thickness of SiN is greater than or equal to 0.05 μm and less than or equal to 0.09 μm.

A gate material layer is deposited on the side of the second gate insulation layer 42 away from the substrate 1. The material of the gate material layer can be molybdenum, nickel, nickel manganese alloy, nickel chromium alloy, nickel molybdenum iron alloy, etc. The thickness of the gate material layer is greater than or equal to 0.25 μm and less than or equal to 0.3 μm. Use a digital exposure machine or a mask to form a gate mask, and then use CF4+O2 for dry etching, which can be performed with high CF4+ low O2 dry etching mixed gas. Specifically, the CF4 flow rate can be 2000 sccm˜2500 sccm (standard cubic centimeter per minute, standard ml/min), the O2 flow rate can be 1000 sccm˜1500 sccm. After dry etching, the polysilicon in contact with the source electrode 74 and the drain electrode 75 is doped and conductive by using the gate self-alignment process, and the phosphine or borane can be used for doping. Then, the mask photoresist is wet stripped, and after the photoresist is wet stripped, moderate doping is performed to form an LDD (lightly doped drain structure) to reduce leakage current. Then, annealing is performed to repair the polysilicon (active layer 3), the first gate insulation laver 41 and the second gate insulation layer 42 damaged by ion doping (the first gate insulation laver 41 and the second gate insulation layer 42 require annealing to repair lattice disorder caused by ion doping bombardment during ion implantation). The annealing temperature is 500-600° C.

An interlayer dielectric layer 6 is deposited on the side of the gate electrode 5 away from the substrate 1. The interlayer dielectric layer 6 can be a combination of SiO and SiN. The thickness of SiO is greater than or equal to 0.2 μm and less than or equal to 0.5 μm. The thickness of SiN is greater than or equal to 0.2 μm and less than or equal to 0.3 μm. Photolithography is performed on the mask layer on the interlayer dielectric layer 6 to form a first via pattern, and then dry etching is performed on the interlayer dielectric layer 6 to form a first via hole 61. The dry etching can be performed by using CF4+O2, and the first via hole 61 is connected to the active layer 3.

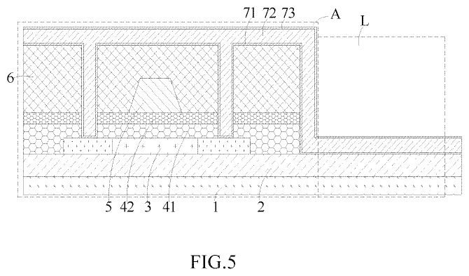

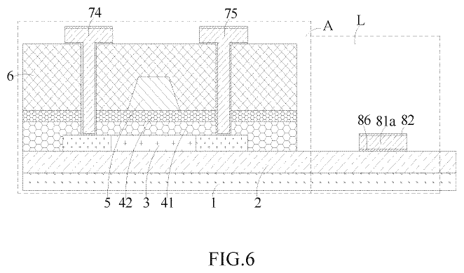

Referring to FIG. 5, a first conductor layer 71, a second conductor layer 72 and a third conductor layer 73 are sequentially deposited on the side of the interlayer dielectric layer 6 away from the substrate 1. The first conductor layer 71, the second conductor layer 72 and the third conductor layer 73 form a source-drain metal layer, and the material of the source-drain metal layer is, for example, Ti—Al—Ti, that is, the material of the first conductor layer 71 is Ti, the material of the second conductor layer 72 is Al, and the material of the third conductor layer 73 is Ti. It should be noted that the materials of the above-mentioned three conductor layers (the first conductor layer 71, the second conductor layer 72 and the third conductor layer 73) are only examples and are not limited, and other metals may also be used. The thickness of Ti is greater than or equal to 300 angstroms and less than or equal to 600 angstroms; the thickness of Al is greater than or equal to 6000 angstroms and less than or equal to 6500 angstroms. Referring to FIG. 6, a digital exposure machine or a mask is used to form a mask for the source-drain layer, and Cl2+O2 is used to etch the source-drain metal layer to form the source electrode 74 and the drain electrode 75 in the light-emitting area A, and form the sixth isolation pattern 86, the first isolation layer 81a and the second isolation pattern 82 in the isolation area L.

Of course, in other exemplary embodiments of the present disclosure, in the case where the source-drain metal layer does not include the first conductor layer 71, the sixth isolation pattern 86 may not be formed; the first conductor layer 71 may also not be formed in the isolation area L, and the sixth isolation pattern 86 will not be formed subsequently.

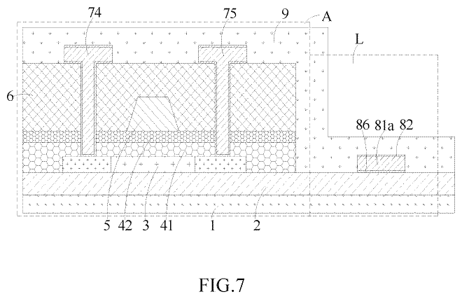

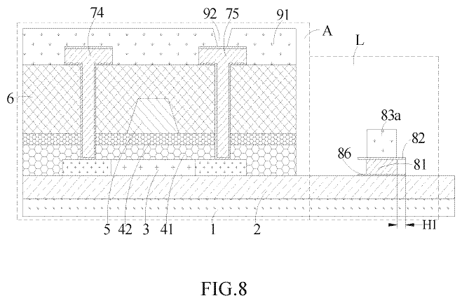

Referring to FIG. 7, a planarization material layer 9 is formed by coating and forming on the side of the source electrode 74, the drain electrode 75 and the second isolation pattern 82 away from the substrate 1. Referring to FIG. 8, the planarization material layer 9 is then subjected to etching and post-baking processes to form a planarization layer 91 in the light-emitting area A, and a second via hole 92 is formed on the planarization layer 91. The second via hole 92 is connected to the source electrode 74, of course, the second via hole 92 can also be connected to the drain electrode 75. In the isolation area L, a third isolation layer 83a is formed on the side of the second isolation pattern 82 away from the substrate 1. The third isolation layer 83a does not cover the side surfaces of the sixth isolation pattern 86, the first isolation layer 81a and the second isolation pattern 82. Therefore, in the process of etching the planarization material layer 9, the planarization layer 91 developer (TMAH tetramethylammonium hydroxide) will corrode the first isolation layer 81a (Al) due to alkalinity, so that the first isolation layer 81a is retracted to form the first isolation pattern 81, that is, the orthographic projection of the first isolation pattern 81 on the substrate 1 is located within the orthographic projection of the second isolation pattern 82 on the substrate 1, and the orthographic projection of the first isolation pattern 81 on the substrate 1 is located within the orthographic projection of the sixth isolation pattern 86 on the substrate 1. The sixth isolation pattern 86, the first isolation pattern 81 and the second isolation pattern 82 form a first-layer “I”-shaped structure. Moreover, for the edges of the source electrode 74 and the drain electrode 75 located in the light-emitting area A, the Al layer will not be corroded due to the coverage of the planarization layer 91.

The thicknesses of the planarization layer 91 and the third isolation layer 83a are greater than or equal to 1.5 μm and less than or equal to 2 μm. The distance H1 between the edge of the first isolation pattern 81 and the edge of the second isolation pattern 82 is greater than or equal to 0.2 μm and less than or equal to 0.3 μm.

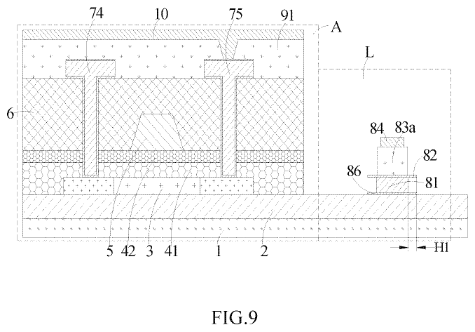

Referring to FIG. 9, a first electrode material layer is formed by sequentially depositing ITO, Ag and ITO. ITO. Ag and ITO on the side of the planarization layer 91 and the third isolation layer 83a away from the substrate 1; a reflective anode layer mask is formed by using a digital exposure machine or a mask, and wet etching is performed so that the first electrode material layer forms the first electrode 10 in the light-emitting area A, and the fourth isolation pattern 84 is formed in the isolation area L; when wet etching the first electrode material layer, the first isolation pattern 81 (Al) of the isolation area L is also etched so that the distance H1 between the edge of the first isolation pattern 81 and the edge of the second isolation pattern 82 is larger, which further increases the climbing difficulty of the light-emitting layer 13 and the second electrode 14, and increases the barrier effect.

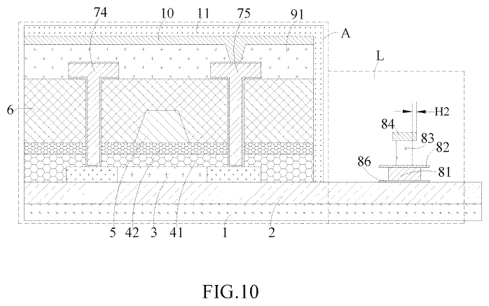

Referring to FIG. 10, a protective layer 11 is formed by coating on the side of the first electrode 10 away from the substrate 1 and on sidewalls of the interlayer dielectric layer, the planarization layer and the first electrode, and a protective layer 11 is not formed on the side of the fourth isolation pattern 84 away from the substrate 1. That is, the protective layer 11 is formed in the light-emitting area, and the protective layer 11 is not formed in the isolation area. The thickness of the protective layer 11 is greater than or equal to 2.5 μm and less than or equal to 3 μm. Then, the third isolation pattern 83 is formed by performing ashing process on the third isolation layer 83a. Since the side of the third isolation layer 83a close to the substrate 1 is protected by the second isolation pattern 82, the side of the third isolation layer 83a away from the substrate 1 is protected by the fourth isolation pattern 84, while the sidewall of the third isolation layer 83a does not have any protective layer 11, the sidewall of the third isolation layer 83a is etched by the ashing process to form the third isolation pattern 83, so that the orthographic projection of the third isolation pattern 83 on the substrate 1 is located within the orthographic projection of the fourth isolation pattern 84 on the substrate 1, and the orthographic projection of the third isolation pattern 83 on the substrate 1 is located within the orthographic projection of the second isolation pattern 82 on the substrate 1. The second isolation pattern 82, the third isolation pattern 83 and the fourth isolation pattern 84 form a second-layer “I”-shaped structure. While the third isolation layer 83a is subjected to ashing process, the protective layer 11 is also subjected to ashing process to remove the protective layer 11. The ashing process can be performed with pure O2, CF4+O2 or SF6+O2. The protective layer 11 is ashed to greater than or equal to 2 μm and less than or equal to 2.5 μm, so that the distance H2 between the edge of the third isolation pattern 83 and the edge of the fourth isolation pattern 84 is greater than or equal to 0.5 μm and less than or equal to 0.75 μm.

Referring to FIG. 1, a pixel definition material layer is formed by coating on the side of the first electrode 10 and the fourth isolation pattern 84 away from the substrate 1, and the thickness of the pixel defining material layer is greater than or equal to 1.4 μm and less than or equal to 1.8 μm. Then, the pixel definition material layer is etched through the processes of exposure, development and post-baking. In the light-emitting area A, the pixel definition material layer forms the pixel definition layer 12, and a third via hole is formed on the pixel definition layer 12. The third via hole is connected to the first electrode 10. In the isolation area L, the pixel definition material layer forms a fifth isolation pattern 85. The fifth isolation pattern 85 further increases the height of the barrier structure 8, and the orthographic projection of the fifth isolation pattern 85 on the substrate 1 is located within the orthographic projection of the fourth isolation pattern 84 on the substrate 1, that is, the edge of the fifth isolation pattern 85 is concave relative to the edge of the fourth isolation pattern 84; or the orthographic projection of the fourth isolation pattern 84 on the substrate 1 is located within the orthographic projection of the fifth isolation pattern 85 on the substrate 1, that is, the edge of the fifth isolation pattern 85 is convex relative to the edge of the fourth isolation pattern 84. That is to say, the edge of the fifth isolation pattern 85 is not aligned with the edge of the fourth isolation pattern 84, thereby further increasing the climbing difficulty of the light-emitting layer 13 and the second electrode 14, weakening the climbing ability of the light-emitting layer 13 and the second electrode 14, increasing the barrier effect, and improving the reliability of the barrier structure 8.

Of course, in other exemplary embodiments of the present disclosure, the fifth isolation pattern 85 may not be formed on the side of the fourth isolation pattern 84 away from the substrate 1.

A light-emitting material layer is formed on the side of the pixel definition layer 12 away from the substrate 1, and a light-emitting layer 13 is formed by etching the light-emitting material layer. The light-emitting layer 13 is located in the third via hole, and the light-emitting layer 13 is connected to the first electrode 10.

A second electrode 14 is formed on the side of the light-emitting layer 13 away from the substrate 1, and the second electrode 14 is connected to the light-emitting layer 13. The second electrode 14 may be a cathode.

It should be noted that although the various steps of the preparation method of a light-emitting panel in the present disclosure are described in a specific order in the drawings, this does not require or imply that these steps must be performed in the specific order, or that all steps shown must be performed to achieve the desired result. Additionally or alternatively, certain steps may be omitted, multiple steps may be combined into one step for execution, and/or one step may be decomposed into multiple steps for execution, and the like.

Further, an embodiment of the present disclosure provides a light-emitting apparatus, and the light-emitting apparatus may include the light-emitting panel described in any one of the above. The specific structure of the light-emitting panel has been described in detail above, so it will not be repeated here.

Functionally, the light-emitting apparatus may be an illumination device or a display device. And the specific type of the light-emitting apparatus is not particularly limited, and any type of illumination device or display device commonly used in the art can be used. In the case where the light-emitting apparatus is a display device, such as a mobile device such as a mobile phone, a wearable device such as a watch, a VR device, etc., those skilled in the art can make corresponding selections according to the specific use of the display device, which is not repeated here.

It should be noted that, in addition to the light-emitting panel, the light-emitting apparatus also includes other necessary components. Take a display as an example, other necessary components include a casing, a circuit board, a power cord, etc. Those skilled in the art can supplement accordingly based on the specific usage requirements of the light-emitting apparatus, which will not be repeated here.

Compared with the prior art, the beneficial effects of the light-emitting apparatus provided by the exemplary embodiments of the present disclosure are the same as the beneficial effects of the light-emitting panel provided by the above-described exemplary embodiments, which will not be repeated here.

Other embodiments of the present disclosure will readily occur to those skilled in the art upon consideration of the specification and practice of the disclosure disclosed herein. This application is intended to cover any variations, usages, or adaptations of the present disclosure that follow the general principles of the present disclosure and include common knowledge or techniques in the art not disclosed by the present disclosure. The specification and embodiments are to be regarded as exemplary only, with the true scope and spirit of the disclosure being indicated by the appended claims.

1. A light-emitting panel having a light-emitting area and an isolation area adjacent to the light-emitting area, wherein the light-emitting panel comprises:
a substrate;
a barrier structure, disposed on one side of the substrate and located in the isolation area;
the barrier structure comprises: a first isolation pattern, a second isolation pattern, a third isolation pattern and a fourth isolation pattern stacked in sequence, the first isolation pattern is closer to the substrate than the fourth isolation pattern; an orthographic projection of the first isolation pattern on the substrate is located within an orthographic projection of the second isolation pattern on the substrate, and an orthographic projection of the third isolation pattern on the substrate is located within an orthographic projection of the fourth isolation pattern on the substrate, and the orthographic projection of the third isolation pattern on the substrate is located within the orthographic projection of the second isolation pattern on the substrate.

2. The light-emitting panel according to claim 1, wherein the barrier structure further comprises:
a fifth isolation pattern disposed on one side of the fourth isolation pattern away from the substrate, wherein an orthographic projection of the fifth isolation pattern on the substrate is located within the orthographic projection of the fourth isolation patter on the substrate, or the orthographic projection of the fourth isolation pattern on the substrate is located within an orthographic projection of the fifth isolation pattern on the substrate.

3. The light-emitting panel according to claim 1, wherein the barrier structure further comprises:
a sixth isolation pattern disposed between the substrate and the first isolation pattern, wherein the orthographic projection of the first isolation pattern on the substrate is located within an orthographic projection of the sixth isolation patter on the substrate.

4. The light-emitting panel according to claim 2, wherein, in the light-emitting area, the light-emitting panel comprises:
a plurality of pixel units arranged in an array, each of the pixel units comprises at least three sub-pixels, each of the sub-pixels comprises a thin film transistor and a light-emitting unit, the thin film transistor comprises a gate electrode, a gate insulation layer, an active layer, a source electrode, a drain electrode and a planarization layer, the light-emitting unit comprises a first electrode, a pixel definition layer, a light-emitting layer and a second electrode.

5. The light-emitting panel according to claim 4, wherein the first isolation pattern, the second isolation pattern and the sixth isolation pattern are provided in a same layer and with a same material as the source electrode and the drain electrode.

6. The light-emitting panel according to claim 4, wherein the third isolation pattern and the planarization layer are provided in a same layer and with a same material.

7. The light-emitting panel according to claim 4, wherein the fourth isolation pattern and the first electrode are provided in a same layer and with a same material.

8. The light-emitting panel according to claim 4, wherein the fifth isolation pattern and the pixel definition layer are provided in a same layer and with a same material.

9. A preparation method of a light-emitting panel, comprising:
providing a substrate, wherein the substrate has a light-emitting area and an isolation area adjacent to the light-emitting area;
forming a first isolation pattern and a second isolation pattern sequentially on one side of the substrate and in the isolation area, wherein an orthographic projection of the first isolation pattern on the substrate is located within an orthographic projection of the second isolation pattern on the substrate;
forming a third isolation pattern and a fourth isolation pattern sequentially on one side of the second isolation pattern away from the substrate, wherein an orthographic projection of the third isolation pattern on the substrate is located within an orthographic projection of the fourth isolation pattern on the substrate, and the orthographic projection of the third isolation pattern on the substrate is located within the orthographic projection of the second isolation pattern on the substrate.

10. The preparation method of the light-emitting panel according to claim 9, wherein the preparation method further comprises:
forming an active layer, a gate insulation layer and a gate electrode on one side of the substrate and in the light-emitting area, wherein the gate insulation layer is located between the active layer and the gate electrode;
forming an interlayer dielectric layer on one side of the active layer or the gate electrode away from the substrate, and forming a first via hole on the interlayer dielectric layer, wherein the first via hole is connected to the active layer;
forming a source electrode and a drain electrode on one side of the interlayer dielectric layer away from the substrate, wherein the source electrode and the drain electrode are connected to the active layer through the first via hole;
forming a planarization layer on one side of the source electrode and the drain electrode away from the substrate, and forming a second via hole on the planarization layer, wherein the second via hole is connected to the source electrode or the drain electrode;
forming a first electrode on one side of the planarization layer away from the substrate, wherein the first electrode is connected to the source electrode or the drain electrode through the second via hole;
forming a pixel definition layer on one side of the first electrode away from the substrate.

11. The preparation method of the light-emitting panel according to claim 10, wherein the first isolation layer and the second isolation pattern are sequentially formed in a patterning process of forming the source electrode and the drain electrode.

12. The preparation method of the light-emitting panel according to claim 11, wherein a third isolation layer is formed in a patterning process of forming the planarization layer, and the first isolation pattern is formed by etching the first isolation layer.

13. The preparation method of the light-emitting panel according to claim 10, wherein a sixth isolation pattern is further formed in the patterning process of forming the source electrode and the drain electrode, and the sixth isolation pattern is provided between the substrate and the first isolation pattern, and the orthographic projection of the first isolation pattern on the substrate is located within an orthographic projection of the sixth isolation pattern on the substrate.

14. The preparation method of the light-emitting panel according to claim 10, wherein the fourth isolation pattern is formed in a patterning process of forming the first electrode.

15. The preparation method of the light-emitting panel according to claim 14, wherein after forming the first electrode and the fourth isolation pattern, the preparation method further comprises:
forming a protective layer on the side of the first electrode away from the substrate and on sidewalls of the interlayer dielectric layer, the planarization layer and the first electrode;
forming the third isolation pattern by ashing the third isolation layer, so that the orthographic projection of the third isolation pattern on the substrate is located within the orthographic projection of the fourth isolation pattern on the substrate, and the orthographic projection of the third isolation pattern on the substrate is located within the orthographic projection of the second isolation pattern on the substrate.

16. The preparation method of the light-emitting panel according to claim 10, wherein, in the patterning process of forming the pixel definition layer, a fifth isolation pattern is formed on one side of the fourth isolation layer away from the substrate, an orthographic projection of the fifth isolation pattern on the substrate is located within the orthographic projection of the fourth isolation pattern on the substrate, or the orthographic projection of the fourth isolation pattern on the substrate is located within an orthographic projection of the fifth isolation pattern on the substrate.

17. A light-emitting apparatus comprising the light-emitting panel according to claim 1.
